(19) United States
(12) Patent Application Publication
(10) Pub. No.: US 2014/0138132 A1
(43) Pub. Date: May 22, 2014

(54) PRINTED CIRCUIT BOARD AND MANUFACTURING METHOD THEREOF

(71) Applicant: Samsung Electro-Mechanics Co., Ltd., Suwon (KR)

(72) Inventor: John Su Kyon, Busan (KR)

(73) Assignee: Samsung Electro-Mechanics Co., Ltd., Suwon (KR)

(21) Appl. No.: 14/045,377

(22) Filed: Oct. 3, 2013

(30) Foreign Application Priority Data
Nov. 20, 2012 (KR) 10-2012-0131549

(51) Int. Cl. H05K 3/44; H05K 1/02

(52) U.S. Cl. CPC H05K 3/445; H05K 1/0201
USPC 174/257; 216/18; 205/126

(57) ABSTRACT

Disclosed herein are a printed circuit board and a manufacturing method thereof. In the manufacturing method of the printed circuit board according to the exemplary embodiment of the present invention, primary copper plating layers are first formed on each of upper and lower surface portions of a core layer in a symmetrical structure, an insulating layer is formed on the primary copper plating layer of the upper surface side, and a secondary copper plating layer is continuously formed on the primary copper plating layer of only the lower surface side. Therefore plating thicknesses required for the front side and the rear side in an asymmetric structure may be uniform to have no plating deviation and non-peeling of an insulating layer (a dry film) for a circuit protection is prevented to have no short defect, thereby making it possible to form a fine circuit pattern.

### CROSS REFERENCE(S) TO RELATED APPLICATIONS

This application claims the benefit under 35 U.S.C. Section 119 of Korean Patent Application Serial No. 10-2012-0131549, entitled “Printed Circuit Board and Manufacturing Method Thereof” filed on Nov. 20, 2012, which is hereby incorporated by reference in its entirety into this application.

### BACKGROUND OF THE INVENTION

1. Technical Field

The present invention relates to a printed circuit board and a manufacturing method thereof, and more particularly, to a printed circuit board of an asymmetric structure formed to have plating thicknesses of a front side and a rear side of the board different from each other and a manufacturing method thereof.

2. Description of the Related Art

As a printed circuit board for a semiconductor has recently been miniaturized and ultra-thinned, a design of the board of an asymmetric structure has been required. Here, the asymmetric structure is a structure formed to have plating thicknesses of a front side and a rear side of the board different from each other, where the front side has a plating thickness formed thereon relatively thinner than that of the rear side in order to form a fine circuit and mount a semiconductor chip, and the rear side has a plating thickness formed thereon relatively thicker than that of the front side in order to provide heat radiation characteristics and power transfer characteristics.

FIGS. 1A to 1D are views showing manufacturing processes of the printed circuit board of the asymmetric structure according to the related art.

Referring to FIG. 1A, in a manufacturing method of the printed circuit board of the asymmetric according to the related art, first, epoxy resin layers 102 as an insulating material are each formed on both surfaces (upper and lower surfaces in FIG. 1A) of the core layer 101, and each of the epoxy resin layers 102 is provided with via holes 102v for electrically conducting between upper and lower portions of the core layer 101.

Next, chemical copper foils (electroless copper plating layers) 103 are each formed across a surface of the epoxy resin layer 102 and an inner surface of the via hole 102v. Next, dry films 104 as an insulating material for a circuit protection are formed on each of surfaces of the chemical copper foils (the electroless copper plating layers) 103 in a predetermined pattern. In this case, as copper plating thicknesses for circuit formation of the front side and the rear side to be performed in a subsequent process become different from each other, the above-mentioned dry film 104 also has a different thickness in proportion to circuit thicknesses of the front side and the rear side.

Next, as shown in FIG. 1B, electrolyte copper plating layers 105 having a predetermined pattern are formed in each of spaces between dry films 104 having the predetermined pattern on the front side and the rear side. In this case, when forming the electrolyte copper plating layers 105 having the asymmetric structure on the front side and the back side, as described above, a difference occurs between current density applied to the front side for plating copper and current density applied to the rear side. Therefore, the front side and the rear side affect each other due to the plating structure. As a result, deviation occurs in the plating thickness, and particularly, the front side is affected by the rear side, such that it is difficult to control the plating thickness.

Meanwhile, after each forming the copper plating layers 105, as shown in FIG. 1C, the dry films 104 between the electrolyte copper plating layers 105 are removed. In this case, as described above, in the case in which the plating thickness becomes thicker due to the deviation in the plating thickness during the formation of the electrolyte copper plating layer 105, as shown in drawings, non-peeling portion 104r of the dry film 104 occurs.

Next, as shown in FIG. 1D, the chemical copper foil (the electroless copper plating layer) 103 is removed to thereby complete a circuit. In this case, the non-peeling portion 104r of the dry film generated in the process of removing the dry film 104 in FIG. 1C as described above is still remaining on the completed circuit and a short occurs in a region in which the above-mentioned non-peeling portion 104r is present. This leads to defective products and causes reliability of the products to be deteriorated.

### RELATED ART DOCUMENT

### Patent Document

(Patent Document 1) Korean Patent Laid-Open Publication No. 10-2012-0048409 (laid-open published on May 15, 2012)

(Patent Document 2) Korean Patent Laid-Open Publication No. 10-2010-0019781 (laid-open published on Feb. 19, 2010)

### SUMMARY OF THE INVENTION

An object of the present invention is to provide a printed circuit board having an asymmetric structure capable of uniformly satisfying plating thicknesses required for a front side and a rear side in an asymmetric plating structure formed to have the plating thicknesses of the front side and the rear side of the board different from each other, having no plating deviation to thereby prevent non-peeling of a dry film and not causing a short defect, and forming a fine circuit, and a manufacturing method thereof.

According to an exemplary embodiment of the present invention, there is provided a printed circuit board, including: a core configuring a central portion of the board; insulating layers formed on each of an upper surface (a front side) and a lower surface (a rear side) of the core layer and each provided with via holes for electrically conducting between upper and lower portions of the core layer; primary copper plating layers formed on the insulating layers formed on each of the upper and lower surface portions of the core layer at and in a predetermined thickness and pattern; and a secondary copper plating layer having a predetermined thickness continuously formed on the primary copper plating layer formed on the lower surface portion of the core layer.

An insulating material of the insulating layer may be an epoxy resin.

The primary and secondary copper plating layers may be formed by an electrolyte copper plating.

The primary copper plating layer on the upper surface (the front side) of the core layer may be formed at a thickness of 8 μm to 10 μm and the primary and secondary copper plating layers on the lower surface (the rear side) of the core layer may have a summation thickness of 18 μm to 20 μm.

According to another exemplary embodiment of the present invention, there is provided a manufacturing method of a printed circuit board, the method including: a) forming insulating layers on each of an upper surface (a front side) and a lower surface (a rear side) of a core layer; b) forming via holes for electrically conducting between upper and lower portions of the core layer in each of the insulating layers; c) forming copper (Cu) foil layers across a surface of each of the insulating layers and an inner surface of the via hole; d) forming first insulating layers for circuit protection on each of the copper foil layers in a predetermined pattern; e) forming primary copper plating layers for forming a circuit on each of the copper foil layers exposed between the first insulating layers for the circuit protection at a predetermined thickness; f) forming a second insulating layer for the circuit protection on the primary copper plating layer formed on the upper surface (the front side); g) forming a secondary copper plating layer for forming a circuit on the primary copper plating layer formed on the lower surface (the rear side) at a predetermined thickness; h) removing the first and second insulating layers for the circuit protection on the upper surface (the front side) portion and the lower surface (the rear side) portion of the core layer; and i) removing the copper foil layer in a region exposed by removing the first and second insulating layers for the circuit protection to complete the circuit.

In step a), an insulating material of the insulating layer may be an epoxy resin.

In step c), the copper foil layer may be formed by an electroless copper plating.

Insulating materials of the first and second insulating layers of the circuit protection may be a dry film or a photosensitive film.

The primary and secondary copper plating layers may be formed by an electrolyte copper plating.

The primary copper plating layer on the upper surface (the front side) of the core layer may be formed at a thickness of 8 μm to 10 μm and the primary and secondary copper plating layers on the lower surface (the rear side) of the core layer may have a summation thickness of 18 μm to 20 μm.

### BRIEF DESCRIPTION OF THE DRAWINGS

FIGS. 1A to 1D are views sequentially showing manufacturing processes of a printed circuit board of an asymmetric structure according to the related art;

FIG. 2 is a view showing the structure of a printed circuit board according to an exemplary embodiment of the present invention;

FIGS. 3A to 3F are views sequentially showing manufacturing processes according to a manufacturing method of the printed circuit board according to the exemplary embodiment of the present invention; and

FIG. 4 is a flow chart showing processes of performing a manufacturing method of the printed circuit board according to the exemplary embodiment of the present invention.

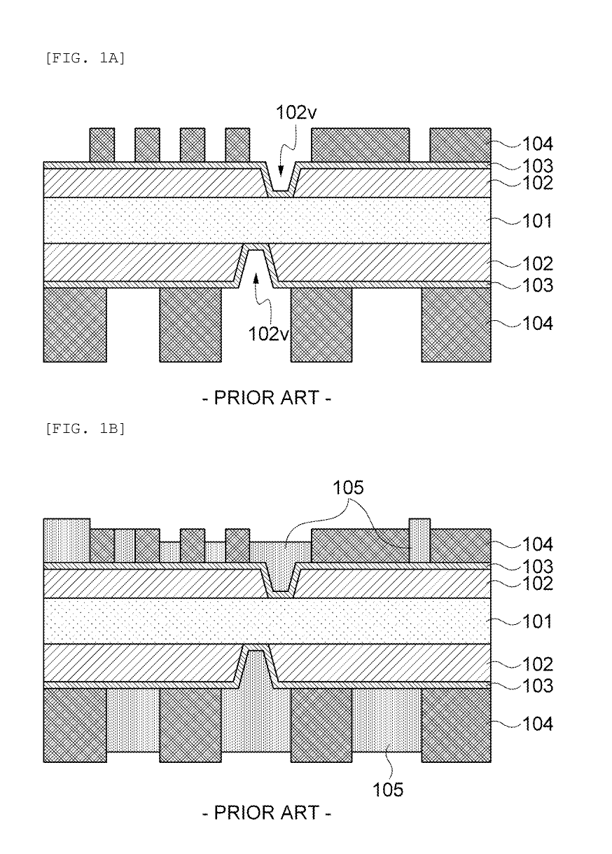

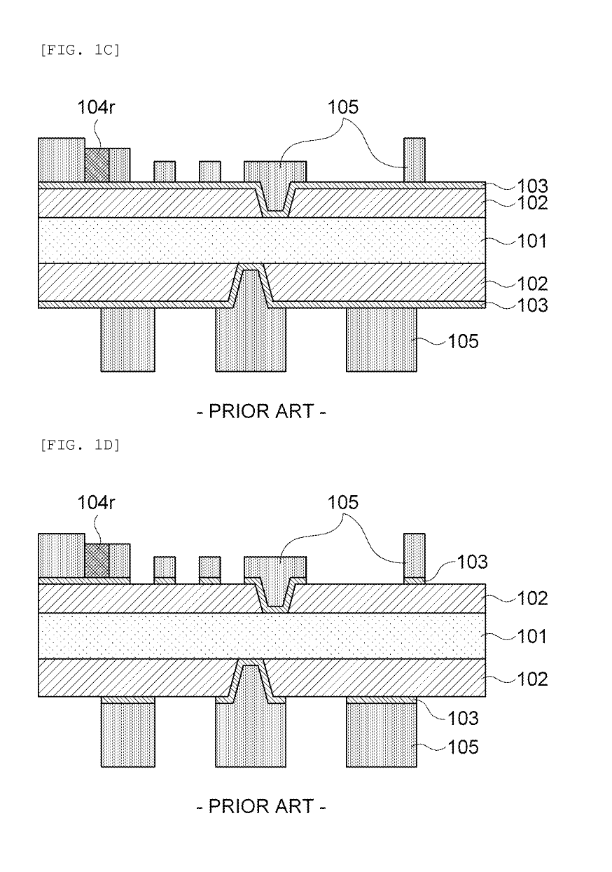

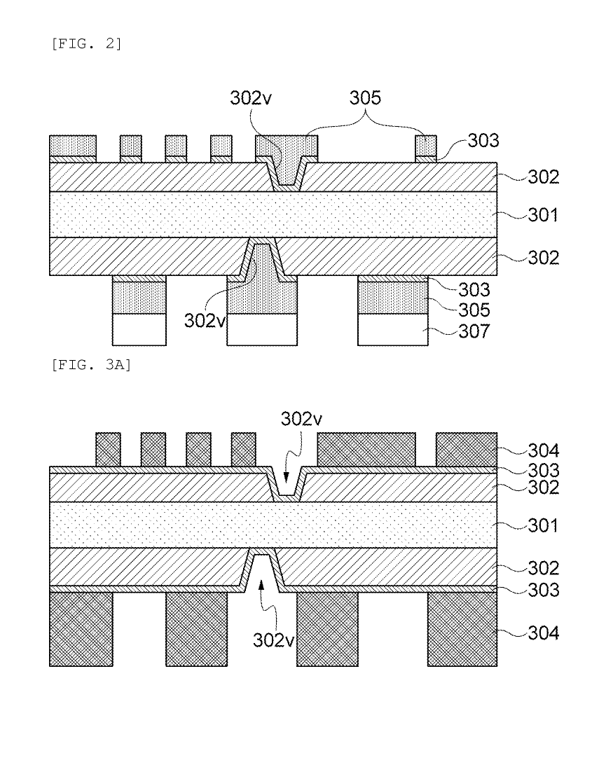

### DESCRIPTION OF THE PREFERRED EMBODIMENTS

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

Through the present specification, unless explicitly described otherwise, “comprising” any components will be understood to imply the inclusion of other components but not the exclusion of any other components. The terms “unit”, “module”, “device” or the like means a unit processing at least one function or operation, which may be implemented by a hardware, a software, or combinations of the hardware and the software.

Hereinafter, embodiments of the present invention will be described in detail with reference to the accompanying drawings.

FIG. 2 is a view showing the structure of a printed circuit board according to an exemplary embodiment of the present invention.

Referring to FIG. 2, the printed circuit board includes a core layer 301, insulating layers 302, primary copper plating layers 305, and secondary copper plating layers 307.

The core layer 301 configures a central part of the board. The above-mentioned core layer 301 may be configured of a single layer and may be configured of a plurality of layers.

The insulating layers 302 are formed on each of an upper surface (a front side) and a lower surface (a rear side) of the core layer 301. In this case, an epoxy resin may be used as an insulating material of the insulating layer 302. In addition, each of the above-mentioned insulating layers 302 is provided with via holes 302v for electrically conducting between upper and lower portions of the core layer 301. Dry etching or wet etching may be used to form the above-mentioned via hole 302, but preferably, the dry etching is used to form a fine circuit pattern.

The primary copper plating layers 305 are formed on the insulating layers 302 formed on the upper and lower surface portions of the core layer 301 at and in a predetermined thickness and pattern. Here, the above-mentioned primary copper plating layer 305 may be formed by an electrolyte copper plating. In addition, the primary copper plating layer 305 is preferably formed at a thickness of 8 μm to 10 μm. This is to satisfy a design value required in relation to a miniaturization and an ultra-thinning trend of the printed circuit board for a semiconductor.

The secondary copper plating layers 307 are continuously formed on the primary copper plating layer 305 formed on the lower surface portion of the core layer 301 at a predetermined thickness. Here, the above-mentioned secondary copper plating layer 307 may also be formed by the electrolyte copper plating. The primary and secondary copper plating layers 305 and 307 on the lower surface (the rear side) of the core layer 301 are formed so as to have a summation thickness of 18 μm to 20 μm.

Next, processes of manufacturing the printed circuit board having the structure as described above according the exemplary embodiment of the present invention will be described.

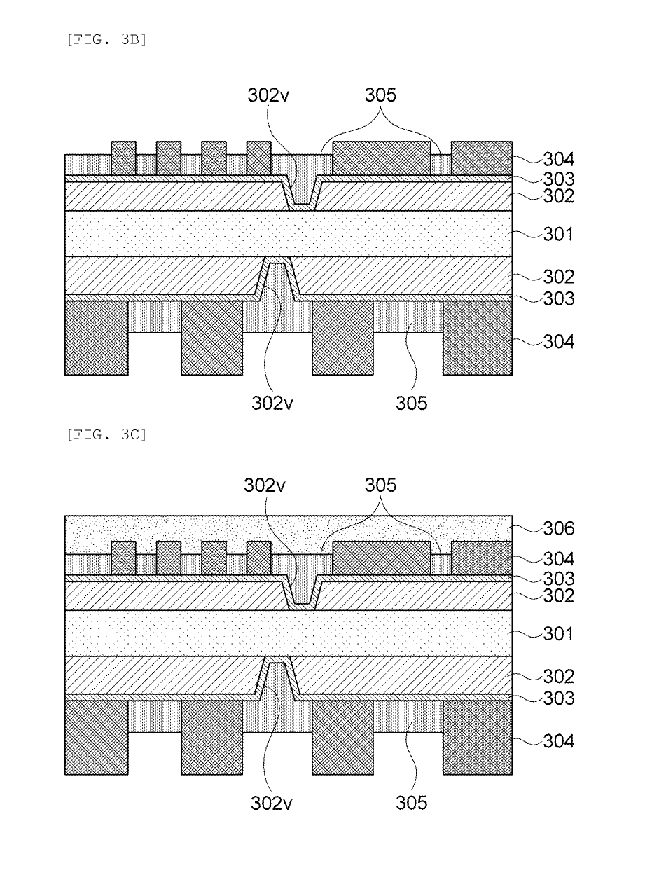

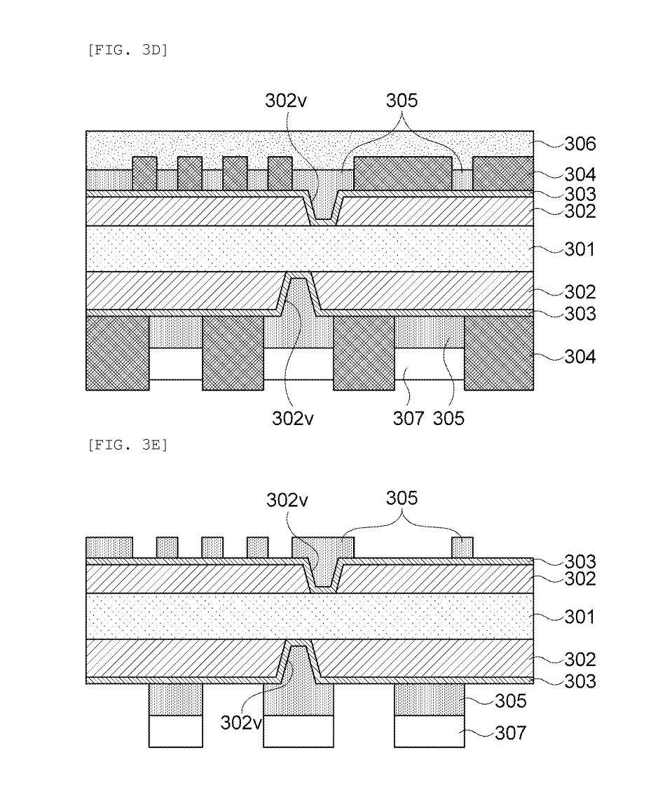

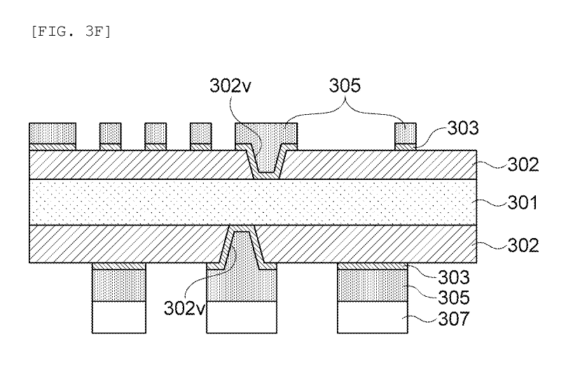

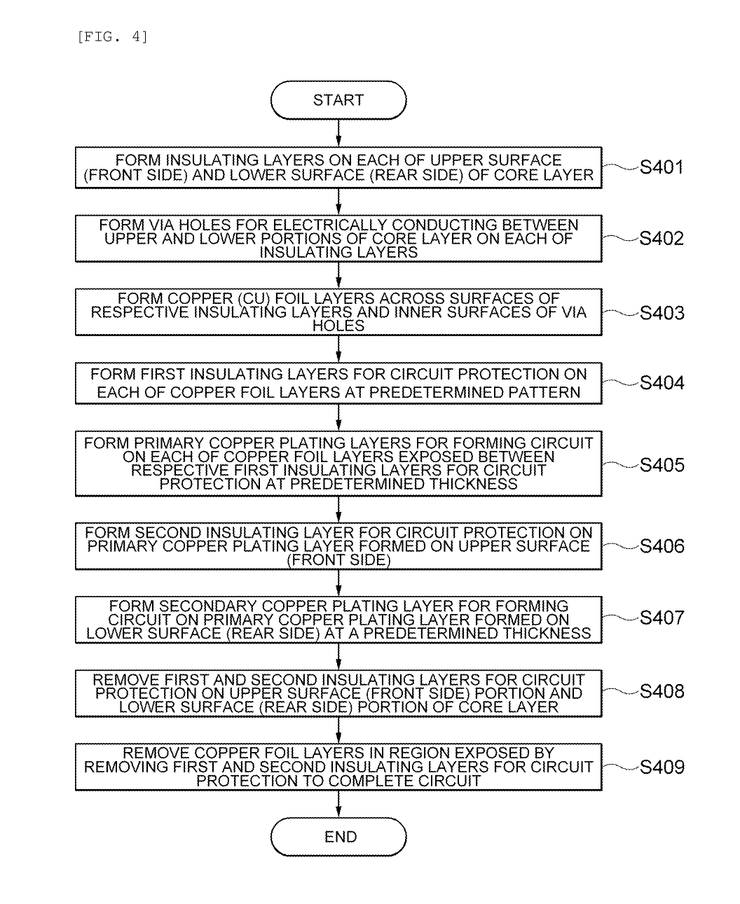

FIGS. 3A to 3F are views sequentially showing manufacturing processes according to a manufacturing method of the printed circuit board according to the exemplary embodiment of the present invention and FIG. 4 is a flow chart showing processes of performing a manufacturing method of the printed circuit board according to the exemplary embodiment of the present invention.

Referring to FIGS. 3A and 4, according to the manufacturing method of the printed circuit board according to the exemplary embodiment of the present invention, first, insulating layers 302 are formed on each of the upper surface (the front side) and the lower surface (the rear side) of the core layer 301 (S401). In this case, an epoxy resin may be used as an insulating material of the above-mentioned insulating layer 302. In addition, the above-mentioned insulating layer 302 may be formed by applying and the epoxy resin on both surfaces of the core layer 301 and then curing the epoxy resin.

When the formation of the insulating layer 302 is completed, via holes 302v for electrically conducting between upper and lower portions of the core layer 301 are formed on each of the insulating layers 302 (S402). In this case, dry etching or wet etching may be used to form the above-mentioned via hole 302v, but preferably, the dry etching is used in consideration of the formation of a fine circuit pattern and the like. In addition, excimer laser, CO₂ laser, and the like may be used for the dry etching.

When the formation of the via hole 302v is completed as described above, copper (Cu) foil layers 303 are formed across surfaces of respective insulating layers 302 and inner surfaces of the via holes 302v (S403). In this case, the above-mentioned copper foil layer 303 may be formed by an electroless copper plating (a chemical plating). The above-mentioned formation of the copper foil layer 303 is to smooth a subsequent formation of a copper plating layer.

After the formation of the copper foil layer 303, first insulating layers 304 for a circuit protection are formed on each of the copper foil layers 303 in a predetermined pattern (S404). In this case, a dry film or a photosensitive film may be used as an insulating material of the above-mentioned first insulating layer 304 for the circuit protection. In addition, in order to form the first insulating layer 304 for the circuit protection having the predetermined pattern, photolithography using a mask may be used.

As described above, when the formation of the first insulating layer 304 for the circuit protection is completed, as shown in FIG. 3B, the primary copper plating layers 305 for forming a circuit are formed on each of the copper foil layers 303 exposed between respective first insulating layers 304 for the circuit protection at a predetermined thickness (S405). Here, the above-mentioned primary copper plating layer 305 may be formed by the electrolyte copper plating. In addition, as described above, the primary copper plating layer 305 is formed at a thickness of 8 μm to 10 μm to satisfy the design value required in relation to the miniaturization and ultra-thinning trend of the printed circuit board for the semiconductor.

After forming the primary copper plating layers 305 on each of the upper and lower portions of the core layer 301, as shown in FIG. 3C, a second insulating layer 306 for a circuit protection is formed on the primary copper plating layer 305 formed on the upper surface (the front side) of the core layer 301 (S406). In this case, the dry film or the photosensitive film may be used as the insulating material of the above-mentioned second insulating layer 306 for the circuit protection, similar to the first insulating layer 304.

When the formation of the second insulating layer 306 for the circuit protection is completed, as shown in FIG. 3D, a secondary copper plating layer 307 for forming a circuit is formed on the primary copper plating layer 305 formed on the lower surface (the rear side) of the core layer 301 at a predetermined thickness (S407). Here, the above-mentioned secondary copper plating layer 307 may also be formed by the electrolyte copper plating, similar to the primary copper plating layer 305. In addition, the primary and secondary copper plating layers 305 and 307 on the lower surface (the rear side) of the core layer are formed so as to have a summation thickness of 18 μm to 20 μm. This is to satisfy the design value required in relation to the miniaturization and ultra-thinning trend of the printed circuit board for the semiconductor and also to improve heat radiation characteristics and power transfer characteristics.

Here, as described above, the primary copper plating layers 305 are first formed on each of the upper and lower surface portions of a core layer 301 in a symmetrical structure, the second insulating layer 306 is formed on the primary copper plating layer 305 of the upper surface side, and the secondary copper plating layer 307 is continuously formed on the primary copper plating layer 305 of only the lower surface side, such that the plating thicknesses required for the front side and the rear side in the asymmetric structure may be uniform.

As described above, when the formation of the secondary copper plating layer 307 is completed, as shown in FIG. 3E, the first and second insulating layers 304 and 306 for the circuit protection on the upper surface (the front side) portion and the lower surface (the rear side) portion of the core layer 301 are removed (S408).

Next, as shown in FIG. 3F, the copper foil layers 303 in the region exposed by removing the first and second insulating layers 304 and 306 for the circuit protection are removed to complete the circuit (S409). In this case, flash etching may be used to remove the copper foil layer 303.

According to the exemplary embodiment of the present invention, primary copper plating layers are first formed on each of upper and lower surface portions of a core layer in a symmetrical structure, an insulating layer is formed on the primary copper plating layer of the upper surface side, and a secondary copper plating layer is continuously formed on the primary copper plating layer of only the lower surface side, such that plating thicknesses required for the front side and the rear side in an asymmetric structure may be uniform to have no plating deviation and non-peeling of an insulating layer (a dry film) for a circuit protection is prevented to have no short defect, thereby making it possible to form a fine circuit pattern.

Although the preferred embodiments of the present invention have been disclosed, the present invention is not limited thereto, but those skilled in the art will appreciated that various modifications, additions and substitutions are possible, without departing from the scope and spirit of the invention as disclosed in the accompanying claims. Therefore, the true scope of the present invention should be construed by the following claims, and all of the technical spirit of the present invention within equivalent range thereof are included in scope of the present invention.

1. A printed circuit board, comprising:
a core configuring a central portion of the board;
insulating layers formed on each of an upper surface (a front side) and a lower surface (a rear side) of the core layer and each provided with via holes for electrically conducting between upper and lower portions of the core layer;
primary copper plating layers formed on the insulating layers formed on each of the upper and lower surface portions of the core layer at and in a predetermined thickness and pattern; and
a secondary copper plating layer having a predetermined thickness continuously formed on the primary copper plating layer formed on the lower surface portion of the core layer.

2. The printed circuit board according to claim 1, wherein an insulating material of the insulating layer is an epoxy resin.

3. The printed circuit board according to claim 1, wherein the primary and secondary copper plating layers are formed by an electrolyte copper plating.

4. The printed circuit board according to claim 1, wherein the primary copper plating layer on the upper surface (the front side) of the core layer is formed at a thickness of 8 μm to 10 μm.

5. The printed circuit board according to claim 1, wherein the primary and secondary copper plating layers on the lower surface (the rear side) of the core layer have a summation thickness of 18 μm to 20 μm.

6. A manufacturing method of a printed circuit board, the method comprising:
forming insulating layers on each of an upper surface (a front side) and a lower surface (a rear side) of a core layer;
forming via holes for electrically conducting between upper and lower portions of the core layer in each of the insulating layers;
forming copper (Cu) foil layers across a surface of each of the insulating layers and an inner surface of the via hole;
forming first insulating layers for circuit protection on each of the copper foil layers in a predetermined pattern;
forming primary copper plating layers for forming a circuit on each of the copper foil layers exposed between the first insulating layers for the circuit protection at a predetermined thickness;
forming a second insulating layer for the circuit protection on the primary copper plating layer formed on the upper surface (the front side);
forming a secondary copper plating layer for forming a circuit on the primary copper plating layer formed on the lower surface (the rear side) at a predetermined thickness;
removing the first and second insulating layers for the circuit protection on the upper surface (the front side) portion and the lower surface (the rear side) portion of the core layer; and
removing the copper foil layer in a region exposed by removing the first and second insulating layers for the circuit protection to complete the circuit.

7. The method according to claim 6, wherein in the forming insulating layers, an insulating material of the insulating layer is an epoxy resin.

8. The method according to claim 6, wherein in the forming copper (Cu) foil layers, the copper foil layer is formed by electroless copper plating.

9. The method according to claim 6, wherein insulating materials of the first and second insulating layers of the circuit protection are a dry film or a photosensitive film.

10. The method according to claim 6, wherein the primary and secondary copper plating layers are formed by an electrolyte copper plating.

11. The method according to claim 6, wherein the primary copper plating layer on the upper surface (the front side) of the core layer is formed at a thickness of 8 μm to 10 μm.

12. The method according to claim 6, wherein the primary and secondary copper plating layers on the lower surface (the rear side) of the core layer has a summation thickness of 18 μm to 20 μm.
